(19) United States
(12) Patent Application Publication
(10) Pub. No.: US 2021/0341524 A1
(43) Pub. Date: Nov. 4, 2021

(54) Timing Difference Detection Circuit Capable of Detecting a Phase Difference Between Different Channels

(71) Applicant: Igistec Co., Ltd., Hsinchu City (TW)

(72) Inventor: Tzu-Li Hung, Hsinchu County (TW)

(21) Appl. No.: 17/178,264

(22) Filed: Feb. 18, 2021

Related U.S. Application Data
(60) Provisional application No. 63/017,671, filed on Apr. 30, 2020.

(30) Foreign Application Priority Data
Jan. 6, 2021 (CN) 202110012300.1

(51) Int. Cl. G01R 25/00; H03K 5/01; H03K 5/24

(52) U.S. Cl. CPC G01R 25/005; H03K 5/24; H03K 5/01

(57) ABSTRACT

A timing difference detection circuit includes a first channel, a second channel, a third channel, a waveform conversion unit, a sampling unit and a comparison unit. The first channel to the third channel generate three signals according to a first reference signal. The waveform conversion unit generates three control signals according to the three signals. The sampling unit samples a second reference signal according to the three control signals to generate three sampling signals. The comparison unit generates three comparison signals according to the three sampling signals. A phase difference between the first channel and the second channel is calculated according to the three comparison signals.

### CROSS REFERENCE TO RELATED APPLICATIONS

This application claims priority to Provisional Application No. 63/017,671, filed Apr. 30, 2020, and China Patent Application No. 202110012300.1, filed Jan. 6, 2021, and incorporated herein by reference in its entirety.

### BACKGROUND OF THE INVENTION

### 1. Field of the Invention

The present invention relates to a timing difference detection circuit, and more particularly, to a circuit capable of detecting a phase difference between different channels.

### 2. Description of the Prior Art

In the field of signal detection, there is a need to obtain the timing error (phase difference) of the two channels. For example, after the sound wave is emitted, if the timing error of the transmitted signals between the two channels can be obtained, the distance and depth of the measured object can be obtained accordingly.

To obtain the timing error between the two channels, the times required for the signals to pass through the two channels can be measured, and the two times can be subtracted. Although this method can obtain timing errors, it requires the use of measuring instruments and further analysis of the measurement results, so it is difficult to simplify the hardware and software requirements. In this field, it is also difficult to check which of the two channels leads the other. In addition, precision is also a big problem. When the phase difference between the two channels is quite small, there is a lack of appropriate and simplified solutions in this field to obtain a small phase difference.

### SUMMARY OF THE INVENTION

A timing difference detection circuit comprises a first channel, a second channel, a third channel, a waveform conversion unit, a sampling unit and a comparison unit. The first channel to the third channel generate three signals according to a first reference signal. The waveform conversion unit generates three control signals according to the three signals. The sampling unit samples a second reference signal according to the three control signals to generate three sampling signals. The comparison unit generates three comparison signals according to the three sampling signals. A phase difference between the first channel and the second channel is calculated according to the three comparison signals.

Another timing difference detection circuit comprises a first channel, a second channel, a third channel and a comparison unit. The first channel to the third channel generate three signals according to a reference signal. The comparison unit generates three comparison signals according to the three signals. A phase difference between the first channel and the second channel is calculated according to the three comparison signals.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a first reference signal being input to two channels in an embodiment.

FIG. 2 is a schematic diagram of inputting a first reference signal into three channels in another embodiment.

FIG. 3 is a schematic diagram of a timing difference detection circuit in an embodiment.

FIG. 4 is a schematic diagram of a second reference signal inputted to the timing difference detection circuit in FIG. 3.

FIG. 5 is a schematic diagram of each comparator in the comparison unit of the timing difference detection circuit in FIG. 3.

FIG. 6 is a schematic diagram of the comparator in FIG. 5 used in the detection circuit in FIG. 3.

FIG. 7 is a schematic diagram of a timing difference detection circuit in another embodiment.

### DETAILED DESCRIPTION

FIG. 1 is a schematic diagram of a first reference signal x(t) being input to two channels in an embodiment. As shown in FIG. 1, when the first reference signal x(t) is transmitted through a first channel CH1 and a second channel CH2, its phase and amplitude will change, and can be outputted as a first signal x1 and a second signal x2. The first signal x1 and the second signal x2 can be expressed as A1*x(t+T1) and A2*x(t+T2) respectively, where * is a multiplication symbol, A1 and A2 correspond to the amplitude, and T1 and T2 are delays caused by the first channel CH1 and the second channel CH2 respectively. The phase difference between the first channel CH1 and the second channel CH2 can be expressed as ΔT=T1−T2. If the system wants to know ΔT, it can calculate the cross-correlation between the signals as:

$${Cor}_{12} = \frac{1}{2 T} {\int }_{- T}^{T} A 1 * x ( t + T 1 ) * A 2 * x ( t + T 2 ) dT \qquad ( 1 )$$

The amplitude A1 and A2 after the channel response (channel response) must be evaluated, so the cross-correlation coefficient can be calculated as:

$${ρ}_{12} = \frac{{Cor}_{12}}{A 1 * A 2} \qquad ( 2 )$$

This can then eliminate the amplitude term to evaluate the phase difference.

For example, if the first reference signal x(t) is a sine wave and expressed as sin(2πft), where f is frequency, and t is time. According to the above, the first reference signal x(t) after passing through the first channel CH1 and the second channel CH2 can be expressed as x1=sin(2πft)=A1 sin(2πf(t+T1)) and x2=A2 sin(2πf(t+T2)). Substituting into equation (2), equation (3) can be obtained as:

$${ρ}_{12} = \frac{{Cor}_{12}}{A 1 * A 2} = cos ( 2 π f ( T 1 - T 2 ) ) = cos ( 2 π f ( Δ T ) ) \qquad ( 3 )$$

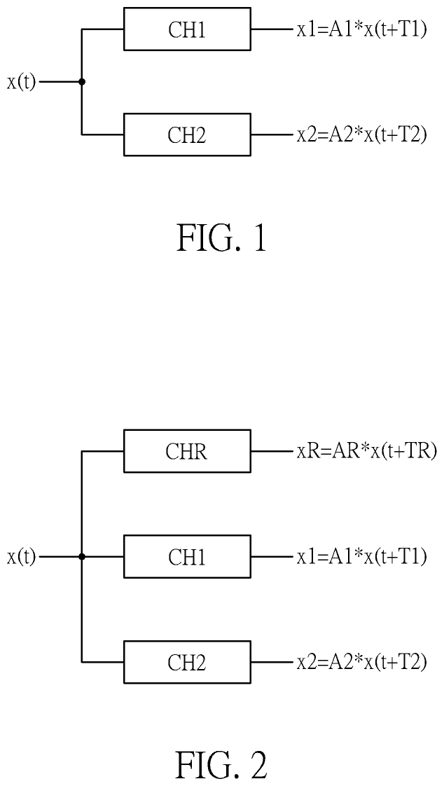

If the frequency of the system is known, the phase difference (T1−T2) can be obtained, which is ΔT. In equation (3), since cosine is an even function, although the value of (T1−T2) can be obtained, the sequence relationship between the first signal x1 and the second signal x2 cannot be known. In order to know which one leads the other, the structure in FIG. 2 can be used.

FIG. 2 is a schematic diagram of inputting the first reference signal x(t) into three channels in another embodiment. The difference between FIG. 2 and FIG. 1 is that the first reference signal x(t) can also enter a third channel CHR to generate a third signal xR=AR*x(t+TR), where AR corresponds to the amplitude, TR is the delay caused by the third channel CHR. By suitable design, the delay TR of the third channel CHR can be smaller than the delay T1 of the first channel CH1 and smaller than the delay T2 of the second channel CH2. The third channel CHR may be a dummy channel, that is, a known reference channel for obtaining the phase difference ΔT. Comparing the cross-correlation between the first channel CH1 and the third channel CHR, and the cross-correlation between the second channel CH2 and the third channel CHR, the following equations can be obtained:

$$\begin{matrix}{ρ}_{1 R} = \frac{{Cor}_{1 R}}{A 1 * AR} = cos ( 2 π f ( T 1 - TR ) ) & ( 4 ) \\ {ρ}_{2 R} = \frac{{Cor}_{1 R}}{A 2 * AR} = cos ( 2 π f ( T 2 - TR ) ) & ( 5 ) \\ {ρ}_{1 R} - {ρ}_{2 R} = - 2 sin ( π f ( T 1 - T 2 ) ) sin ( π f ( T 1 + T 2 - 2 TR ) ) & ( 6 )\end{matrix}$$

Assuming that the system design can affirm T1+T2−2TR>0, the polarity and magnitude relationship of the timing phases of the signals can be evaluated according to the calculation of ρ1R−ρ2R in equation (6).

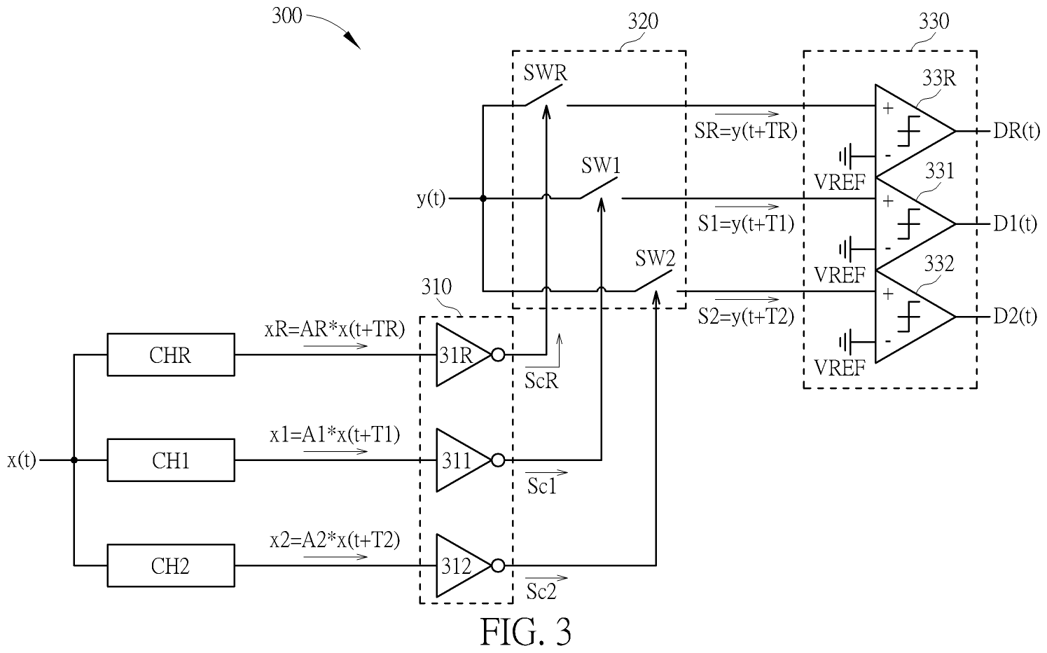

However, a more complicated circuit such as a multiplier is required to perform the above calculations on amplitude and correlation. Therefore, the embodiment further provides a detection circuit to simplify signal processing. FIG. 3 is a schematic diagram of the timing difference detection circuit 300 in the embodiment. The detection circuit 300 includes a first channel CH1, a second channel CH2, a third channel CHR, a waveform conversion unit 310, a sampling unit 320, and a comparison unit 330. The first channel CH1 to the third channel CHR receive the first reference signal x(t) to generate the first signal x1, the second signal x2, and the third signal xR respectively.

The waveform conversion unit 310 receives the first signal x1, the second signal x2, and the third signal xR to generate the first control signal Sc1, the second control signal Sc2, and the third control signal ScR, respectively. The sampling unit 320 uses the first control signal Sc1, the second control signal Sc2, and the third control signal ScR to sample the second reference signal y(t) to generate the first sampling signal S1, the second sampling signal S2, and the third sampling signal SR. The comparison unit 330 generates a first comparison signal D1(t), a second comparison signal D2(t), and a third comparison signal DR(t) according to the first sampling signal S1, the second sampling signal S2, and the third sampling signal SR, respectively. Among them, the first control signal Sc1, the second control signal Sc2, and the third control signal ScR can be respectively expressed as: Sc1=y(t+T1), Sc2=y(t+T2) and ScR=y(t+TR).

The first channel CH1 and the second channel CH2 are channels to be tested, and the third channel CHR is a known channel. The first comparison signal D1(t), the second comparison signal D2(t) and the third comparison signal DR(t) are used to calculate the phase difference ΔT between the first channel CH1 and the second channel CH2.

In FIG. 3, the circuit before the waveform conversion unit 310 is the same as FIG. 2. However, in FIG. 3, the behavior of the signals passing through the channels CH1, CH2, CH3 are no longer detected, but the signals passing through the channels CH1, CH2, CH3 and then converted by the waveform conversion unit 310 are used as the control signals Sc1, Sc2, ScR to sample the second reference signal y(t) to generate the sampling signals S1, S2, SR which are passed to the comparison unit 330 to obtain the comparison signals D1(t), D2(t) and DR(t). Since the second reference signal y(t) is known, the cross-correlation between the comparison signals D1(t), D2(t) and DR(t) can be calculated to obtain the required T1−T2, which is ΔT. When the comparison signals D1(t), D2(t) and DR(t) output by the comparison unit 330 are one-bit (1 bit) signals, a simple digital logic can be used to complete the subsequent calculation work, greatly simplifying the required circuit complexity.

According to an embodiment, as shown in FIG. 3, the waveform conversion unit 310 comprises a first waveform converter 311, a second waveform converter 312, and a third waveform converter 31R, respectively receiving the first signal x1, the second signal x2 and the third signal xR, thereby respectively generating the first control signal Sc1, the second control signal Sc2, and the third control signal ScR. The waveform converters 311, 312, and 31R can convert the signals x1, x2, and xR into control signals Sc1, Sc2 and ScR with signal edges, for example, from a sine wave to a square wave, so as to control the sampling unit 320. For example, the waveform converters 311, 312, and 31R may be inverters.

According to an embodiment, as shown in FIG. 3, the sampling unit 320 includes a first switch SW1, a second switch SW2, and a third switch SWR, which are respectively controlled by the first control signal Sc1, the second control signal Sc2, and the third control signal ScR to generate the first sampling signal S1, the second sampling signal S2, and the third sampling signal SR, respectively.

Since the delay TR of the third channel CHR is the shortest, the third sampling signal SR can be sampled and output first. Then, if the delay T1 of the first channel CH1 is shorter than the delay T2 of the second channel CH2, the first sampling signal S1 will be sampled and output before the second sampling signal S2; otherwise, the first sampling signal S1 will follow the second sampling signal S2 to be sampled and output.

According to an embodiment, as shown in FIG. 3, the comparison unit 330 comprises a first comparator 331, a second comparator 332, and a third comparator 33R, which compare the first sampling signal S1 with the reference voltage VREF, and compare the second sampling signal S2 and the reference voltage VREF, and compare the third sampling signal SR and the reference voltage VREF to generate a first comparison signal D1(t), a second comparison signal D2(t), and a third comparison signal DR(t), respectively. The first comparator 331, the second comparator 332, and the third comparator 33R can be equivalent to a one-bit analog-to-digital converter to generate one-bit comparison signals D1(t), D2(t) and DR(t).

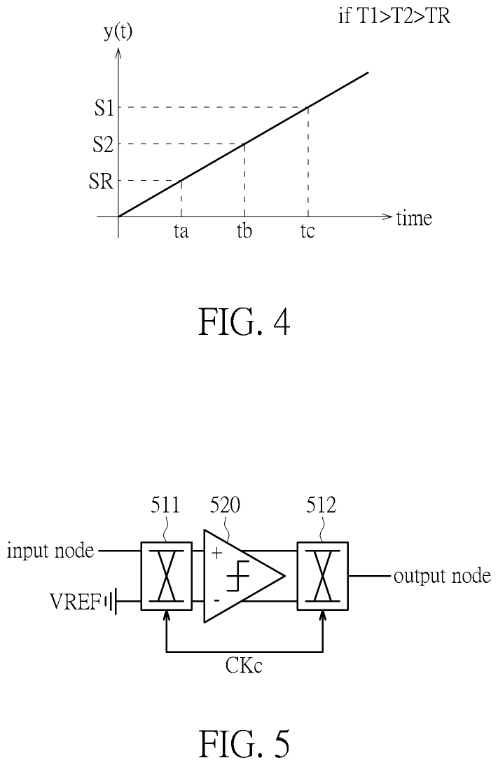

FIG. 4 is a schematic diagram of the second reference signal y(t). FIG. 4 is only an example, not to limit the scope of the embodiment. As shown in FIG. 4, the second reference signal y(t) is a linear signal, and its voltage can rise linearly over time with a single slope. Assuming that the delay T1 of the first channel CH1 is longer than the delay T2 of the second channel CH2, the sampling signals SR, S2, and S1 are output at time points ta, tb, and tc, respectively. As shown in FIG. 4, the voltage of the sampling signal S1 is higher than the voltage of the sampling signal S2, and the voltage of the sampling signal S2 is higher than the voltage of the sampling signal SR. In the comparison unit 330, since the voltage of the sampling signal S1 is higher than the voltage of the sampling signal S2, after comparing with the reference voltage VREF, the values of the comparison signals D1(t) and D2(t) can be 1 and 0. Since the second reference signal y(t) is a given signal, the slope of FIG. 4 can be adjusted by slowing down the slope, the values of the comparison signals D1(t) and D2(t) can be changed to 0 and 0, by In this way, the critical value of the delay T2 of the second channel CH2 can be obtained; in the same way, by adjusting the slope to be steeper, the values of the comparison signals D1(t) and D2(t) can be changed to 1 and 1, thereby, The critical point of the delay T1 of the first channel CH1 can be obtained. According to this principle, the delays T1 and T2 can be obtained based on the comparison signals D1(t) and D2(t).

FIG. 5 is a schematic diagram of each comparator in the comparison unit 330 of FIG. 3. Each of the comparators 331, 332, and 33R may include a first chopper 511, a comparison element 520, and a second chopper 512. The comparison element 520 can be coupled between the first chopper 511 and the second chopper 512, and the choppers 511 and 512 are controlled by a chopper clock signal CKc.

Using the choppers 511 and 512 can eliminate the interference of the offset voltage. Because the choppers 511 and 512 can switch the inputs of the comparison element 520, the offset voltage generated by the comparison element 520 will be at the positive node once and at the negative node the other time. But for the input nodes, when the offset voltage is at the positive node, its output is also at the positive node; when the offset voltage is at the negative node, its output will be reversed. Therefore, no matter what the situation is, the relationship between the output and the input is always the same, and the offset voltage of the comparison element 520 changes from a fixed value to a carrier wave at the output node, and its frequency corresponds to the chopping clock signal CKc. Using the chopping comparator as shown in FIG. 5 can filter out the interference of the offset voltage caused by the sampling of the comparison element 520, and prevent the offset voltage from affecting the timing evaluation.

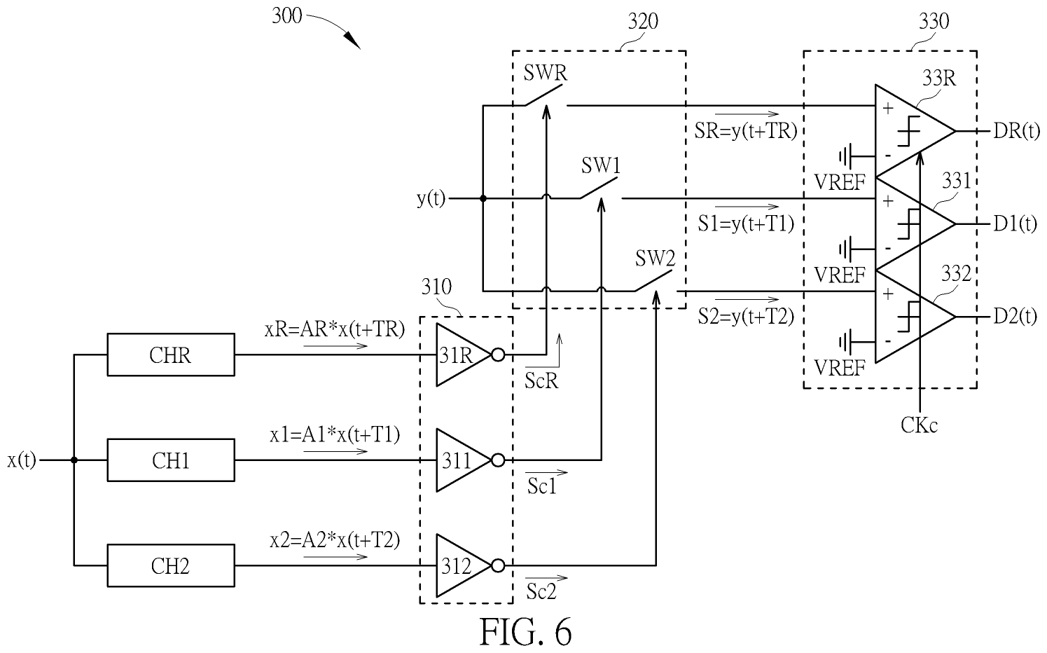

The structure in FIG. 5 can be used selectively. FIG. 6 is a schematic diagram of the comparator in FIG. 5 used in the detection circuit 300 in FIG. 3. By using the comparator in FIG. 5, the offset voltage interference can be reduced. Since the chopper is used, the comparison unit 330 in FIG. 5 receives the chopper clock signal CKc. The operating principle of FIG. 6 is similar to that of FIG. 3, so the description will not be repeated.

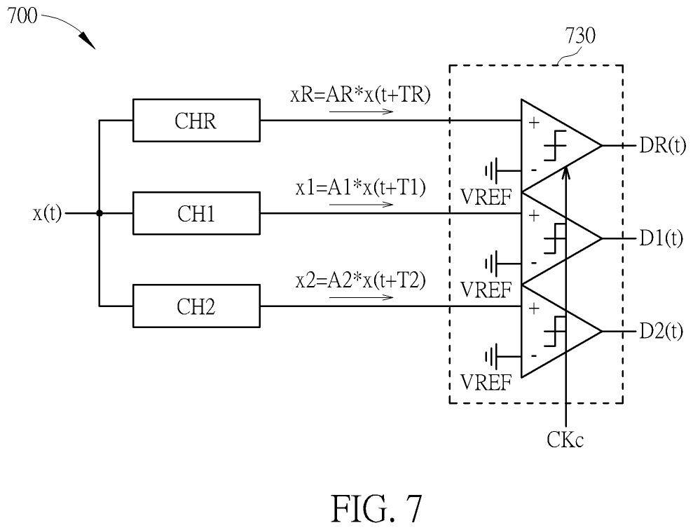

FIG. 7 is a schematic diagram of a timing difference detection circuit 700 in another embodiment. The detection circuit 700 comprises a first channel CH1, a second channel CH2, a third channel CHR, and a comparison unit 730. The first channel CH1, the second channel CH2, and the third channel CHR receive the reference signal x(t) to generate the first signal x1, the second signal x2, and the third signal xR, respectively. Similarly in FIG. 3, the signals x1, x2, and xR can be expressed as x1=A1*x(t+T1), x2=A2*x(t+T2) and xR=A1*x(t+TR), respectively. The comparison unit 730 can generate a first comparison signal D1(t), a second comparison signal D2(t), and a third comparison signal DR(t) according to the signals x1, x2, and xR, respectively. The first and second channels CH1 and CH2 are to be tested, and the third channel CHR is a known channel. The comparison signals D1(t), D2(t) and DR(t) can be used to calculate the phase difference between the first and second channels CH1 and CH2. The difference between FIG. 7 and FIG. 3 is that the detection circuit 700 does not perform a sampling operation. However, the detection circuit 700 is used when the reference signal x(t) is relatively simple. For example, when the reference signal x(t) is a simple linear signal similar to that shown in FIG. 4, the comparison unit 730 can be used to convert the signals x1, x2, and xR into one-bit digital signals as shown in FIG. 7 to obtain the phase difference ΔT between the channels CH1 and CH2. The comparison unit 730 in FIG. 7 receives the chopping clock signal CKc, which is similar to the comparison unit 330 in FIG. 6.

In general, by using the detection circuits 300 and 700 provided in the embodiments, the complexity of the circuit can be effectively simplified, and the phase difference and the sequence relationship of the two channels to be tested can be obtained. In practical applications, such as sonar signal, before and after the ultrasonic wave is transmitted, the channel response is different. By comparing with the reference channel (such as the above-mentioned channel CHR), the distance and depth of the measured object can be found. Another example is the application of TOF (time of flight). After the laser is launched, the measured distance can be obtained by comparing the correlation relationship of the rebounded laser signals. Another example is a low-speed phase detection circuit that can obtain a relatively small phase difference through long-term correlation calculations and comparisons, which helps to improve detection precision. Using the detection circuit provided in the embodiment, the phase sequence of the signals transmitted by the two channels can be confirmed. Therefore, the detection circuit provided by the embodiment is really helpful for solving the problems in the field.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A timing difference detection circuit comprising:
a first channel configured to generate a first signal according to a first reference signal;
a second channel configured to generate a second signal according to the first reference signal;
a third channel configured to generate a third signal according to the first reference signal;
a waveform conversion unit coupled to the first channel, the second channel and the third channel and configured to generate a first control signal, a second control signal and a third control signal according to the first signal, the second signal and the third signal respectively;
a sampling unit coupled to the wave conversion unit and configured to sample a second reference signal according to the first control signal, the second control signal and the third control signal to generate a first sampling signal, a second sampling signal and a third sampling signal respectively; and
a comparison unit coupled to the sampling unit and configured to generate a first comparison signal, a second comparison signal and a third comparison signal according to the first sampling signal, the second sampling signal and the third sampling signal respectively;
wherein a phase difference between the first channel and the second channel is calculated according to the first comparison signal, the second comparison signal and the third comparison signal.

2. The detection circuit of claim 1 wherein the sampling unit comprises:
a first switch configured to sample the second reference signal according to the first control signal to generate the first sampling signal;
a second switch configured to sample the second reference signal according to the second control signal to generate the second sampling signal; and
a third switch configured to sample the second reference signal according to the third control signal to generate the third sampling signal.

3. The detection circuit of claim 1 wherein the comparison unit comprises:
a first comparator configured to compare the first sampling signal and a third reference signal to generate the first comparison signal;
a second comparator configured to compare the second sampling signal and the third reference signal to generate the second comparison signal; and
a third comparator configured to compare the third sampling signal and the third reference signal to generate the third comparison signal.

4. The detection circuit of claim 3 wherein each of the first comparator, the second comparator and the third comparator comprises a first chopper, a second chopper, and a comparison element coupled between the first chopper and the second chopper, the first chopper and the second chopper being controlled by a chopper clock signal.

5. The detection circuit of claim 3 wherein the first comparison signal, the second comparison signal and the third comparison signal are one-bit signals.

6. The detection circuit of claim 1 wherein the waveform conversion unit comprises:
a first waveform converter coupled to the first channel and configured to generate the first control signal according to the first signal;
a second waveform converter coupled to the second channel and configured to generate the second control signal according to the second signal; and
a third waveform converter coupled to the third channel and configured to generate the third control signal according to the third signal.

7. The detection circuit of claim 6 wherein the first waveform converter, the second waveform converter and the third waveform converter are inverters.

8. The detection circuit of claim 1 wherein a delay of the third channel is less than delays of the first channel and the second channel.

9. The detection circuit of claim 1 wherein the first reference signal is a linear signal.

10. A timing difference detection circuit comprising:
a first channel configured to generate a first signal according to a reference signal;
a second channel configured to generate a second signal according to the reference signal;
a third channel configured to generate a third signal according to the reference signal;
a comparison unit configured to generate a first comparison signal, a second comparison signal and a third comparison signal according to the first signal, the second signal and the third signal respectively;
wherein a phase difference between the first channel and the second channel is calculated according to the first comparison signal, the second comparison signal and the third comparison signal.

11. The detection circuit of claim 10 wherein the reference signal is a linear signal.
